(19) United States
(12) Patent Application Publication
(10) Pub. No.: US 2026/0129957 A1
(43) Pub. Date: May 7, 2026

(54) SILICON CARBIDE SEMICONDUCTOR DEVICE

(71) Applicant: FUJI ELECTRIC CO., LTD., Kawasaki-shi (JP)

(72) Inventor: Masakazu BABA, Matsumoto-city (JP)

(73) Assignee: FUJI ELECTRIC CO., LTD., Kawasaki-shi (JP)

(21) Appl. No.: 19/435,090

(22) Filed: Dec. 29, 2025

Related U.S. Application Data
(63) Continuation of application No. PCT/JP2024/042966, filed on Dec. 4, 2024.

(30) Foreign Application Priority Data
Jan. 9, 2024 (JP) 2024-001297

(51) Int. Cl. H10D 84/00; H10D 8/00; H10D 30/66; H10D 62/10; H10D 62/60; H10D 62/832

(52) U.S. Cl. CPC H10D 84/143; H10D 8/411; H10D 30/668; H10D 62/103; H10D 62/126; H10D 62/60; H10D 62/8325

(57) ABSTRACT

A silicon carbide semiconductor device, including: a semiconductor substrate having first and second main surfaces; a first semiconductor region and a second semiconductor region provided in the semiconductor substrate; third semiconductor regions selectively between the first main surface and the second semiconductor region; a plurality of gate electrodes provided in a plurality of trenches via a plurality of gate insulating films, respectively; second-conductivity-type regions selectively provided between the second semiconductor region and the first semiconductor region; first and second electrodes respectively provided on the first and second main surfaces; a fourth semiconductor region between the first main surface and the first semiconductor region; and a first wiring layer provided on the first main surface. The second-conductivity-type regions includes first second-conductivity-type regions apart from the trenches and in contact with the second semiconductor region. The first semiconductor region includes a first first-conductivity-type region having a different dopant concentration.

### CROSS REFERENCE TO RELATED APPLICATIONS

This is a continuation application of International Application PCT/JP2024/042966 filed on Dec. 4, 2024 which claims priority from a Japanese Patent Application No. 2024-001297 filed on Jan. 9, 2024, the contents of which are incorporated herein by reference.

### BACKGROUND OF THE INVENTION

### 1. Field of the Invention

Embodiments of the disclosure relate to a silicon carbide semiconductor device.

### 2. Description of the Related Art

Japanese Patent No. 6617657 describes a technique in which a first p⁺ base region and a second p⁺ base region for electric field relaxation in the vicinity of a bottom of a trench are provided immediately below the trench (side facing an n⁺-type drain region) and between the trench and an adjacent, respectively, and a dopant concentration of an n-type current diffusion layer is made higher only immediately below the second p⁺ base region than in other portions, thereby making the breakdown voltage immediately below the first p⁺ base region higher than the breakdown voltage immediately below the second p⁺ base region. Japanese Laid-Open Patent Publication No. 2020-136416 also describes a similar technique.

### SUMMARY OF THE INVENTION

According to an embodiment of the present disclosure, a silicon carbide semiconductor device includes: a semiconductor substrate having an active region, the semiconductor substrate having a first main surface and a second main surface opposite to each other; a first semiconductor region of a first conductivity type, provided in the semiconductor substrate; a second semiconductor region of a second conductivity type, provided in the active region of the semiconductor substrate, between the first main surface and the first semiconductor region; a plurality of third semiconductor regions of the first conductivity type, selectively provided in the semiconductor substrate between the first main surface and the second semiconductor region; a plurality of trenches penetrating through the plurality of third semiconductor regions and the second semiconductor region in a depth direction of the silicon carbide semiconductor device; a gate insulating film provided in each of the plurality of trenches; a plurality of gate electrodes provided in the plurality of trenches via the gate insulating films, respectively; a plurality of second-conductivity-type regions selectively provided in the semiconductor substrate between the second semiconductor region and the first semiconductor region, reaching a position closer to the second main surface of the semiconductor substrate than are bottoms of the plurality of trenches, the plurality of second-conductivity-type regions being in contact with the first semiconductor region; a first electrode provided on the first main surface in the active region and electrically connected to the plurality of third semiconductor regions, the second semiconductor region and the plurality of second-conductivity-type regions; a second electrode provided on the second main surface; a fourth semiconductor region of the second conductivity type, provided in the semiconductor substrate between the first main surface and the first semiconductor region, and surrounding a periphery of the active region in a plan view of the silicon carbide semiconductor device, the fourth semiconductor region reaching a position closer to the second main surface than are the bottoms of the plurality of trenches and being in contact with the first semiconductor region; and a first wiring layer provided on the first main surface to surround the periphery of the active region, the first wiring layer being connected to a portion of the first electrode and being electrically connected to the fourth semiconductor region, the first wiring layer facing the fourth semiconductor region in the depth direction. The plurality of second-conductivity-type regions includes a plurality of first second-conductivity-type regions provided apart from the plurality of trenches and in contact with the second semiconductor region, each of the plurality of first second-conductivity-type regions having a surface that faces the second main surface. The first semiconductor region includes a first first-conductivity-type region having a dopant concentration different from that of the rest of the first semiconductor region, the first first-conductivity-type region being in contact with said surfaces of the plurality of first second-conductivity-type regions.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout of a silicon carbide semiconductor device according to an embodiment, as viewed from a front side of a semiconductor substrate thereof.

FIG. 2 is a plan view depicting a layout of a cell structure of an active region of FIG. 1 as viewed from the front side of the semiconductor substrate.

FIG. 3 is a cross-sectional view depicting a structure along a cutting line A1-A1′ depicted in FIG. 2.

FIG. 4 is a cross-sectional view depicting the structure along a cutting line A2-A2′ depicted in FIG. 2.

FIG. 5 is a cross-sectional view depicting the structure along a cutting line A3-A3′ depicted in FIG. 2.

FIG. 6 is a cross-sectional view depicting the structure along a cutting line B-B′ depicted in FIG. 2.

FIG. 7 is a cross-sectional view depicting the structure along a cutting line C-C′ depicted in FIG. 1.

FIG. 8 is a cross-sectional view depicting the structure along a cutting line D1-D1′ depicted in FIG. 1.

FIG. 9 is a cross-sectional view depicting the structure along a cutting line D2-D2′ depicted in FIG. 1.

FIG. 10 is a plan view depicting a layout of a silicon carbide semiconductor device of a reference example, as viewed from a front side of a semiconductor substrate thereof.

FIG. 11 is a plan view depicting a layout of a cell structure of an active region in FIG. 10, as viewed from the front side of the semiconductor substrate.

FIG. 12 is a cross-sectional view depicting the structure along a cutting line AA-AA′ in FIG. 11.

FIG. 13 is a cross-sectional view depicting the structure along a cutting line BB-BB′ in FIG. 11.

FIG. 14 is a cross-sectional view depicting the structure along a cutting line CC-CC′ in FIG. 10.

FIG. 15 is a plan view schematically depicting dielectric breakdown (a burn mark of an insulating layer) due to current concentration at coupled ends of a source ring and a source electrode in FIG. 10.

### DETAILED DESCRIPTION OF THE INVENTION

First, problems associated with the conventional techniques are discussed. In the conventional techniques, a portion of an inrush current at the time of turning on the power may concentrate at a portion of an electrode of a MOSFET, and the destruction resistance against the surge current_{IFSM} is reduced.

An outline of an embodiment of the present disclosure is described. (1) A silicon carbide semiconductor device according to one aspect of the present disclosure is as follows. An active region is provided in the semiconductor substrate. A first semiconductor region of a first conductivity type is provided in the semiconductor substrate. A second semiconductor region of a second conductivity type is provided between a first main surface of the semiconductor substrate and the first semiconductor region in the active region. A plurality of third semiconductor regions of the first conductivity type is selectively provided between the first main surface and the second semiconductor region. A plurality of trenches penetrate through the plurality of third semiconductor regions and the second semiconductor region in a depth direction. A plurality of gate electrode is provided in the plurality of trenches via a gate insulating film.

A plurality of second-conductivity-type regions is selectively provided between the second semiconductor region and the first semiconductor region. The plurality of second-conductivity-type regions reaches a position closer to a second main surface of the semiconductor substrate than are bottoms of the plurality of trenches and is in contact with the first semiconductor region. The first electrode is provided on the first main surface in the active region and is electrically connected to the plurality of third semiconductor regions, the second semiconductor region, and the second-conductivity-type regions. A second electrode is provided on the second main surface. A fourth semiconductor region of the second conductivity type is provided between the first main surface and the first semiconductor region. A fourth semiconductor region surrounds a periphery of the active region.

The fourth semiconductor region reaches a position closer to the second main surface than are the bottoms of the plurality of trenches and is in contact with the first semiconductor region. A first wiring layer is provided on the first main surface to surround a periphery of the active region, is coupled to a portion of the first electrode, faces the fourth semiconductor region in a depth direction, and is electrically connected to the fourth semiconductor region. The plurality of second-conductivity-type regions includes a plurality of first second-conductivity-type regions provided apart from the plurality of trenches and in contact with the second semiconductor region. The first semiconductor region selectively includes, in a portion thereof in contact with a surface of the first second-conductivity-type regions, the surface facing the second main surface, a first first-conductivity-type region having a different dopant concentration.

According to the silicon carbide semiconductor device disclosed above, a built-in voltage of pn junctions (main junctions of the MOSFET) between the second-conductivity-type regions of the active region and the first semiconductor region may be partially made equal to or lower than a built-in voltage of a pn junction between the fourth semiconductor region directly below the first wiring layer and the first semiconductor region. Thus, when an inrush current flows through the MOSFET, a forward current preferentially flows through a part of the body diode in the active region, or the forward current simultaneously flows through the body diode directly below the source ring (first wiring layer) and a part of the body diode in the active region. Therefore, the carrier density of the first semiconductor region directly below the source ring is reduced. As a result, the concentration of current at the source ring may be suppressed when an inrush current flows through the MOSFET, and the withstand capability against a surge current may be improved. Thus, the breakdown withstand capability of the MOSFET may be improved.

(2) In the silicon carbide semiconductor device according to the present disclosure, in (1) described above, a dopant concentration of the first first-conductivity-type region may be higher than a dopant concentration of a second first-conductivity-type region of the first semiconductor region, the second first-conductivity-type region being exclusive of the first first-conductivity-type region.

According to the silicon carbide semiconductor device disclosed above, avalanche breakdown may easily occur in the active region, and avalanche resistance may be improved.

(3) In the silicon carbide semiconductor device according to the present disclosure, in (2) described above, the first first-conductivity-type region may be provided between the second semiconductor region and the second first-conductivity-type region, may reach a position closer to the second main surface than are the first second-conductivity-type regions, and may selectively border the surface of the first second-conductivity-type regions.

According to the silicon carbide semiconductor device disclosed above, avalanche breakdown may easily occur in the active region, and avalanche resistance may be improved.

(4) In the silicon carbide semiconductor device according to the present disclosure, in (2) described above, the first semiconductor region may selectively include a plurality of third first-conductivity-type regions between the second first-conductivity-type region and the first second-conductivity-type regions, the plurality of third first-conductivity-type regions being adjacent to the first first-conductivity-type region and having a dopant concentration lower than that of the second first-conductivity-type region.

According to the silicon carbide semiconductor device disclosed above, when an inrush current flows through the MOSFET, a forward current of the body diode preferentially flows to the active region through the plurality of third first-conductivity-type regions. Therefore, the carrier density of the first semiconductor region directly below the source ring may be further reduced.

(5) In the silicon carbide semiconductor device according to the present disclosure, in (1) described above, a dopant concentration of the first first-conductivity-type region may be lower than a dopant concentration of a second first-conductivity-type region of the first semiconductor region, the second first-conductivity-type region being exclusive of the first first-conductivity-type region.

According to the silicon carbide semiconductor device disclosed above, when an inrush current flows through the MOSFET, a forward current of the body diode preferentially flows to the active region through the first first-conductivity-type region. Therefore, the carrier density of the first semiconductor region directly below the source ring may be further reduced.

(6) In the silicon carbide semiconductor device according to the present disclosure, in (5) described above, the first first-conductivity-type region may be provided between the second first-conductivity-type region and the first second-conductivity-type regions.

According to the silicon carbide semiconductor device disclosed above, when an inrush current flows through the MOSFET, a forward current of the body diode preferentially flows to the active region through the first first-conductivity-type region. Therefore, the carrier density of the first semiconductor region directly below the source ring may be further reduced.

(7) In the silicon carbide semiconductor device according to the present disclosure, in (2) described above, the plurality of trenches extends linearly in a first direction parallel to the front surface of the semiconductor substrate. A plurality of first second-conductivity-type regions is scattered at a predetermined interval in the first direction. The first first-conductivity-type region may border the plurality of first second-conductivity-type regions, reach a position closer to the second main surface than is the plurality of first second-conductivity-type regions, and selectively border the surface of the first second-conductivity-type regions.

According to the silicon carbide semiconductor device disclosed above, a portion in which an avalanche current flows at the time of avalanche breakdown and a portion in which a surge current flows when an inrush current flows in the MOSFET may be effectively apart from each other.

(8) In the silicon carbide semiconductor device according to the present disclosure, in (5) described above, the plurality of trenches linearly extends in a first direction parallel to the front surface of the semiconductor substrate. The plurality of the first second-conductivity-type regions is scattered at a predetermined interval in the first direction. The first first-conductivity-type region may be disposed in island shapes each adjacent to a different one of the plurality of first second-conductivity-type regions in the depth direction.

According to the silicon carbide semiconductor device disclosed above, a portion in which an avalanche current flows at the time of avalanche breakdown and a portion in which a surge current flows when an inrush current flows in the MOSFET may be effectively apart from each other.

(9) In the silicon carbide semiconductor device according to the present disclosure, in (7) or (8) described above, the plurality of second-conductivity-type regions includes a plurality of second second-conductivity-type regions facing the bottoms of the plurality of trenches. The plurality of second second-conductivity-type regions may linearly extend in the first direction.

According to the silicon carbide semiconductor device disclosed above, the electric field applied near the bottoms of the plurality of trenches may be relaxed even when the first second-conductivity-type regions are scattered.

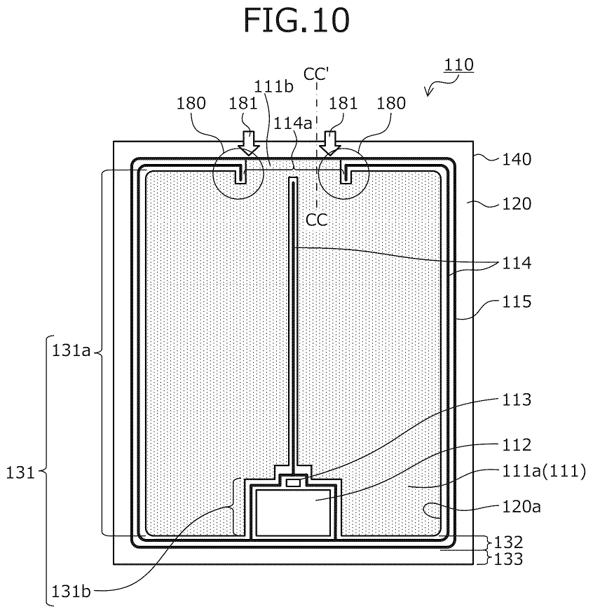

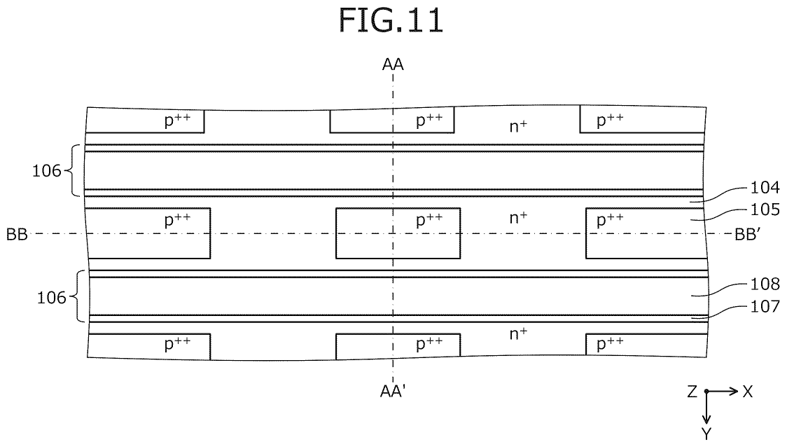

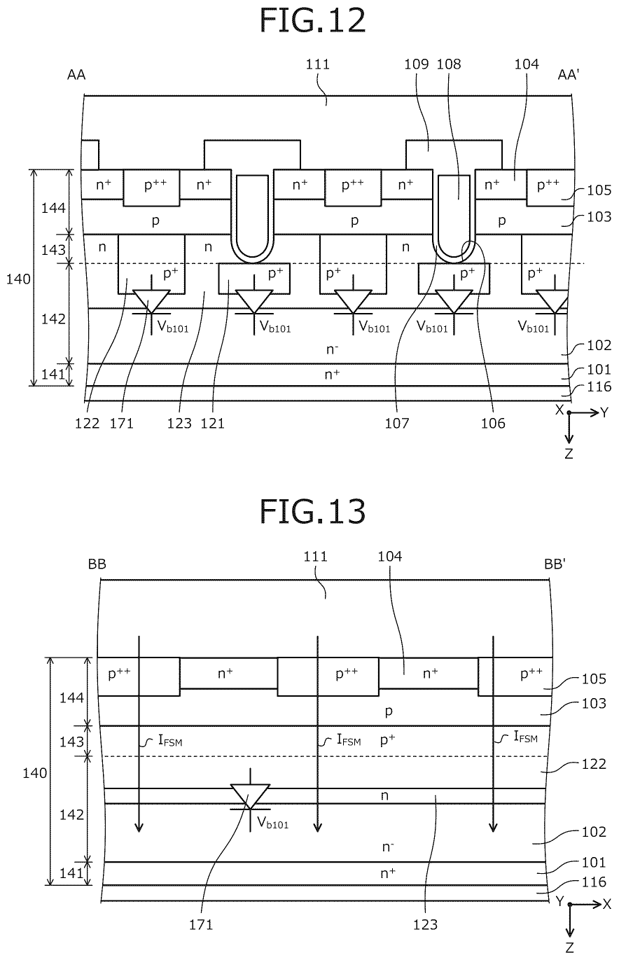

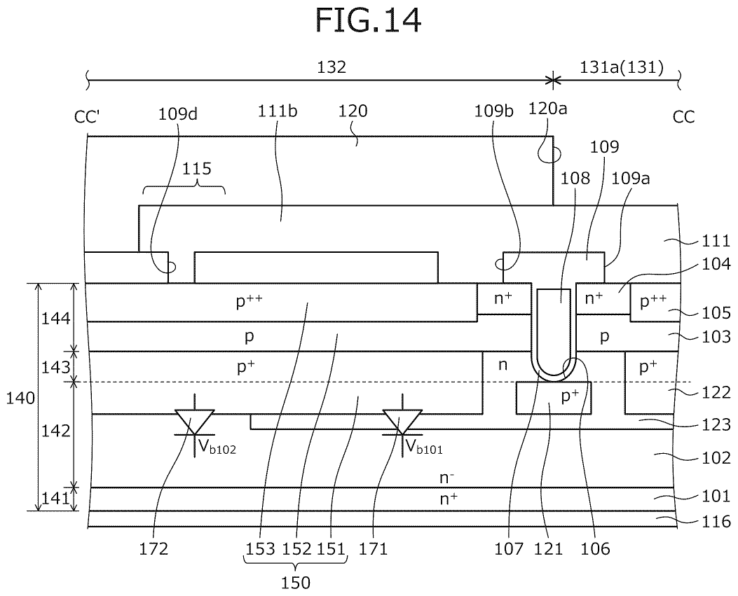

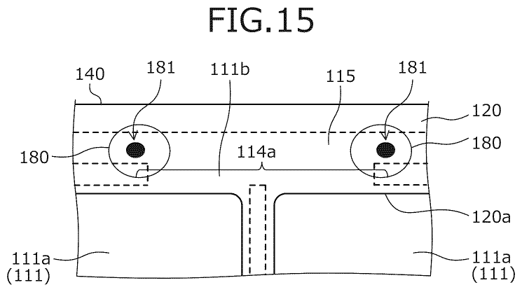

Findings underlying the present disclosure are discussed. First, a structure of a silicon carbide semiconductor device of a reference example will be described. FIG. 10 is a plan view depicting a layout of the silicon carbide semiconductor device of the reference example, as viewed from a front side of a semiconductor substrate thereof. FIG. 11 is a plan view depicting a layout of a cell structure of an active region in FIG. 10, as viewed from the front side of the semiconductor substrate. FIGS. 12 and 13 are cross-sectional views depicting a structure along a cutting line AA-AA′ and a cutting line BB-BB′ in FIG. 11, respectively. FIG. 14 is a cross-sectional view depicting the structure along a cutting line CC-CC′ in FIG. 10. FIG. 15 is a plan view schematically depicting dielectric breakdown (a burn mark of an insulating layer) due to current concentration at coupled ends of a source ring and a source electrode in FIG. 10.

A silicon carbide semiconductor device 110 of the reference example depicted in FIGS. 10 to 14 is a vertical metal oxide semiconductor field effect transistor (MOSFET) having insulated gates of a metal-oxide-semiconductor three-layer structure as a trench gate structure, and having in a boundary region 132 between an active region 131 and an edge termination region 133 of a semiconductor substrate (semiconductor chip) 140 containing silicon carbide (SiC) as a semiconductor material, a gate finger 114 and a source ring 115 so as to surround the periphery of the active region 131 in a plan view.

As depicted in FIG. 10, in a plan view, the active region 131 has a substantially rectangular shape and is provided substantially in a center (chip center) of the semiconductor substrate 140. In an effective region (hereinafter, referred to as an effective active region) 131a of the active region 131, MOSFET cells (functional units of a device) are arranged. A non-operating active region 131b is a region of the active region 131 excluding the effective active region 131a and is free of MOSFET cells. The boundary region 132 is adjacent to an outer side (side facing a chip end) of the active region 131 and surrounds the periphery of the active region 131. The edge termination region 133 is a region between the boundary region 132 and an end (chip end) of the semiconductor substrate 140.

A source pad 111a (source electrode 111), a gate pad 112, a measurement pad 113, the gate finger 114, and the source ring 115 are disposed on the front surface of the semiconductor substrate 140. The source electrode 111 is provided in the effective active region 131a and covers substantially the entire surface of the effective active region 131a. A portion of the source electrode 111 exposed in the opening 120a of the passivation film 120 functions as a source pad 111a (hatched portion). The gate pad 112, the measurement pad 113, and a gate resistor (not depicted) are disposed in the non-operating active region 131b. The measurement pad 113 is an electrode pad for measuring a gate resistance value.

The gate finger 114 is disposed in the non-operating active region 131b and the boundary region 132. The gate finger 114 and the source ring 115 are disposed apart from each other in the boundary region 132 in ring-like shapes concentrically surrounding the periphery of active region 131, in a plan view. The gate finger 114, in a plan view, surrounds the periphery of the active region 131 in a substantially rectangular shape partially opened in the boundary region 132. The gate finger 114 is electrically connected to the gate pad 112 via the gate resistor. Gate electrodes 108 (see FIG. 12) of all the cells of the MOSFET are electrically connected to the gate finger 114.

The source ring 115 is disposed closer to the chip end than is the gate finger 114 in the boundary region 132, and surrounds the periphery of the active region 131 in a substantially rectangular shape in a plan view. The source ring 115 is connected to a p-type outer peripheral region 150 described later and is coupled to the source electrode 111 at a partially opened portion 114a of the gate finger 114 and is e fixed to the potential of the source electrode 111. The source ring 115 has a function of suppressing concentration of a hole current at an insulating layer directly below the gate finger 114 (side facing the semiconductor substrate 140) when holes in an n⁻-type drift region 102 closer to the chip end than is the active region 131 are pulled out to the source electrode 111 when the MOSFET is off.

As depicted in FIGS. 11 to 13, the semiconductor substrate 140 is formed by stacking epitaxial layers 142 to 144, which constitute the n⁻-type drift region 102, an n-type current spreading region 123, and a p-type base region 103, in this order on the front surface of an n⁺-type starting substrate 141 containing SiC as a semiconductor material. The semiconductor substrate 140 has, as a front surface, a main surface having the p-type epitaxial layer 144 and, as a back surface, a main surface having the n⁺-type starting substrate 141. The n⁺-type starting substrate 141 constitutes an n⁺-type drain region 101. In the effective active region 131a, a trench gate structure of the MOSFET is provided between the front surface of the semiconductor substrate 140 and the n⁻-type drift region 102.

The trench gate structure includes the p-type base region 103, n⁺-type source regions 104, p⁺⁺-type contact regions 105, trenches 106, gate insulating films 107, and gate electrodes 108. The p-type base region 103 is provided between the front surface of the semiconductor substrate 140 and the n⁻-type drift region 102 over an entire area of the active region 131 and the boundary region 132. The n⁺-type source regions 104 and the p⁺⁺-type contact regions 105 are each selectively provided in contact with the p-type base region 103 between the front surface of the semiconductor substrate 140 and the p-type base region 103.

The p-type base region 103 and the n⁺-type source regions 104 linearly extend in a longitudinal direction (first direction X) of the trenches 106 between the trenches 106 adjacent to each other. The p⁺⁺-type contact regions 105 are disposed between the trenches 106 adjacent to each other, apart from the trenches 106, and scattered in the longitudinal direction of the trenches 106. The trenches 106 linearly extend in the first direction X, which is parallel to the front surface of the semiconductor substrate 140; the trenches 106 are disposed adjacent to each other in a second direction Y parallel to the front surface of the semiconductor substrate 140 and orthogonal to the first direction X; and the trenches 106 form a stripe pattern when viewed from the front side of the semiconductor substrate 140 (in a plan view) (see FIG. 11).

The trenches 106 penetrate through the n⁺-type source regions 104 and the p-type base region 103 in a depth direction Z and terminate in the n-type current spreading region 123. Between the p-type base region 103 and the n⁻-type drift region 102, first p⁺-type regions 121 and second p⁺-type regions 122 for electric field relaxation and the n-type current spreading region 123 are selectively provided at positions deeper toward the n⁺-type drain region 101 than are the bottoms of the trenches 106. In the effective active region 131a, the first p⁺-type regions 121 and the second p⁺-type regions 122 linearly extend in the longitudinal direction of the trenches 106 by substantially the same length as a length of the trenches 106 in the longitudinal direction, and are in contact with a p-type outer peripheral region 150 described later.

The first p⁺-type regions 121 are provided apart from the p-type base region 103 and faces the bottoms of the trenches 106 in the depth direction Z. The second p⁺-type regions 122 are provided between mutually adjacent trenches 106 and are apart from the first p⁺-type regions 121 and the trenches 106. The second p⁺-type regions 122 each has an upper surface (surface facing the n⁺-type source regions 104) that is in contact with the p-type base region 103. The second p⁺-type regions 122 face the p⁺⁺-type contact regions 105 in the depth direction Z via the p-type base region 103. The second p⁺-type regions 122 are partially connected to the first p⁺-type regions 121 at a portion not depicted.

The n-type current spreading region 123 is adjacent to the first p⁺-type regions 121 and the second p⁺-type regions 122; the n-type current spreading region 123 reaches a position deeper toward the n⁺-type drain region 101 than are the first p⁺-type regions 121 and the second p⁺-type regions 122, and is in contact with the n⁻-type drift region 102. The n-type current spreading region 123 borders an entire area of lower surfaces (surfaces facing the n⁺-type drain region 101) of the first p⁺-type regions 121 and the second p⁺-type regions 122. The n-type current spreading region 123 is provided in the entire region of the active region 131 and extends to the boundary region 132. The n-type current spreading region 123 faces the entire surfaces of the source electrode 111, the gate pad 112, the measurement pad 113, the gate finger 114, and the gate resistor (not depicted) in the depth direction Z.

The gate electrodes 108 are provided in the trenches 106 via the gate insulating films 107. The interlayer insulating film 109 is provided on the entire front surface of the semiconductor substrate 140 and covers the gate electrodes 108. The source electrode 111 is in ohmic contact with the n⁺-type source regions 104 and the p⁺⁺-type contact regions 105 in contact holes 109a and 109b of the interlayer insulating film 109, and is electrically connected to the p-type base region 103, the n⁺-type source regions 104, and the p⁺⁺-type contact regions 105. A drain electrode 116 is provided on the entire back surface of the semiconductor substrate 140 (the back surface of the n⁺-type starting substrate 141).

As depicted in FIG. 14, a p-type outer peripheral region 150 (151 to 153) is provided between the front surface of the semiconductor substrate 140 and the n-type drift region 102 over substantially the entire area of the boundary region 132. The p-type outer peripheral region 150 is connected to the source electrode 111 and the source ring 115, and is fixed to the potential of the source electrode 111. The p-type outer peripheral region 150 surrounds the periphery of the active region 131 in the boundary region 132 and extends over the entire region of the non-operating active region 131b. The p-type outer peripheral region 150 faces the entire surfaces of the gate pad 112, the measurement pad 113, the gate finger 114, the gate resistor, and the source ring 115 in the depth direction Z.

The n-type current spreading region 123 extends from the active region 131 to the entire region between the p-type outer peripheral region 150 and the n⁻-type drift region 102 directly below the gate finger 114 (side facing the n⁺-type drain region 101). The n-type current spreading region 123 terminates closer to the chip center than is the source ring 115 (on the chip center side) in the boundary region 132 and does not face the source ring 115 in the depth direction Z. That is, the lower surface of the p-type outer peripheral region 150 in the boundary region 132 is in contact with the n-type current spreading region 123 only immediately below the gate finger 114, and is in contact with the n⁻-type drift region 102 in a portion closer to the chip end than is the gate finger 114 (including directly below the source ring 115).

In the edge termination region 133, the front surface of the semiconductor substrate 140 is configured by an n⁻-type epitaxial layer 142 (n⁻-type drift region 102). In the edge termination region 133, a predetermined voltage withstanding structure is provided between the front surface of the semiconductor substrate 140 and the n⁻-type drift region 102. In the non-operating active region 131b, the boundary region 132, and the edge termination region 133, the entire front surface of the semiconductor substrate 140 is covered by an insulating layer including a field oxide film and the interlayer insulating film 109. The p-type outer peripheral region 150 of the non-operating active region 131b and the boundary region 132, and the voltage withstanding structure of the edge termination region 133 are covered by the insulating layer.

The gate finger 114 is provided on the field oxide film between the source electrode 111 and the source ring 115. The source electrode 111 and the source ring 115 are in ohmic contact with the p⁺⁺-type outer peripheral contact region 153 through the contact holes 109b and 109d of the insulating layer (the field oxide film and the interlayer insulating film 109), respectively, and are electrically connected to the p-type outer peripheral region 150 (151 to 153). A portion (hereinafter, referred to as a convex portion) 111b of the source electrode 111 extends outward in a convex shape on the interlayer insulating film 109 at a partially opened portion 114a of the gate finger 114 and is connected to the source ring 115 (FIGS. 10 and 14).

In the silicon carbide semiconductor device 110 (MOSFET) of the reference example described above, when a surge current_{IFSM} is generated due to a steep dV/dt (temporal change in voltage) of the drain-source voltage when an inrush current flows in the MOSFET (when an inrush current at the time of power-on flows), the surge current_{IFSM} concentrates in the insulating layer directly below the gate finger 114, and the leakage current_{GSS} increases between the gate and the source. Therefore, the source ring 115 is disposed closer to the chip end than is the gate finger 114, and the surge current_{IFSM} is caused to flow to the source ring 115, thereby suppressing the dielectric breakdown directly below the gate finger 114.

However, the coupled portion of the source electrode 111 and the source ring 115 has, in a plan view, a shape in which an end (a portion surrounded by a circular frame 180 in FIGS. 10 and 15, hereinafter referred to as a coupled end portion) 181 of the elongated metal layer (the source ring 115) is connected to a side surface (convex portion 111b of the source electrode 111 and the source ring 115) of the metal layer having a substantially rectangular shape in a plan view. In FIG. 15, the outline of the source electrode 111 and the outline of the source ring 115 are indicated by broken lines. Therefore, the surge current_{IFSM} flowing into the source ring 115 flows through the source ring 115 toward the source electrode 111, and concentrates at the coupled end portion 181 between the source electrode 111 and the source ring 115.

A reason that the surge current_{IFSM} concentrates at the coupled end portion 181 between the source electrode 111 and the source ring 115 is presumed to be that, since the n-type current spreading region 123 is provided in the active region 131, the surge current_{IFSM} generated when an inrush current flows in the MOSFET is more likely to flow directly below the source ring 115 than in the active region 131. Since the built-in voltage (contact potential difference generated at the pn junction surface) V_{b2} of the parasitic pn junction diode (second body diode) 172 formed directly below the source ring 115 is lower than the built-in voltage V_{b1} of the first body diode 171 formed in the active region 131, the surge current_{IFSM} preferentially flows directly below the source ring 115.

The first body diode 171 is formed by pn junctions of the p⁺⁺-type contact regions 105, the p-type base region 103, the first p⁺-type regions 121, the second p⁺-type regions 122, the n-type current spreading region 123, and the n⁻-type drift region 102. The second body diode 172 is formed by a pn junction between the p-type outer peripheral region 150 and the n⁻-type drift region 102. As depicted in equation (1), the built-in voltage V_{bi} of the pn junction increases as an acceptor density N_{A} and a donor density N_{d} increase. k_{B} is the Boltzmann constant. When the temperature T is room temperature (300 K), k_{B}T is 25.9 meV. q is the charge amount of the electron. nᵢ is the intrinsic carrier density.

$${V}_{b i} = \frac{{k}_{B} T}{q} ln ( \frac{{N}_{D} {N}_{A}}{{n}_{i}^{2}} ) \qquad ( 1 )$$

The built-in voltage V_{b1} of the first body diode 171 is determined by the dopant concentrations of the first p⁺-type regions 121 and the second p⁺-type regions 122 and the dopant concentration of the n-type current spreading region 123. The built-in voltage V_{b2} of the second body diode 172 is determined by the dopant concentration of the p⁺-type outer peripheral region 151 and the dopant concentration of the n⁻-type drift region 102. The p⁺-type outer peripheral region 151 is formed simultaneously with the first p⁺-type regions 121 and the second p⁺-type regions 122, and has the same dopant concentration as the first p⁺-type regions 121 and the second p⁺-type regions 122. Therefore, the first body diode 171 and the second body diode 172 have the same acceptor density N_{A} that determines the built-in voltages V_{b1} and V_{b2}.

The donor density N_{d} that determines the built-in voltage V_{b2} of the second body diode 172 is lower than the donor density N_{d} that determines the built-in voltage V_{b1} of the first body diode 171 because the n-type current spreading region 123 is provided in the active region 131. Therefore, the built-in voltage V_{b2} of the second body diode 172 is lower than the built-in voltage V_{b1} of the first body diode 171. When the body diode of the MOSFET is energized, the second body diode 172 is energized in the forward direction before the first body diode 171 is energized in the forward direction, and the forward current IF starts to flow preferentially through the second body diode 172.

When the body diode of the MOSFET is energized, the forward current IF preferentially flows through the second body diode 172, and carriers (holes and electrons) are more likely to be accumulated in the n⁻-type drift region 102 in the boundary region 132 than in the active region 131. Therefore, when the surge current_{IFSM} is generated when the body diode of the MOSFET is energized, the carrier density of the n⁻-type drift region 102 in the boundary region 132 further increases. When the MOSFET transitions from this state to the OFF state, the amount of hole current flowing from the n⁻-type drift region 102 of the boundary region 132 into the source ring 115 increases.

The hole current flowing into the source ring 115 flows through the source ring 115 toward the source electrode 111, and is concentrated at the coupled end portion 181 between the source electrode 111 and the source ring 115. This problem becomes more conspicuous as the dopant concentration of the n⁻-type drift region 102 becomes lower (that is, as the breakdown voltage of the silicon carbide semiconductor device 110 becomes higher, for example, 3.3 kV or more). As a result, as depicted in FIG. 15, the resistance to the surge current_{IFSM} decreases at the coupled end portion 181 between the source electrode 111 and the source ring 115, and the coupled end portion 181 becomes a dielectric breakdown point (for example, a state in which the surge current_{IFSM} is concentrated and the insulating layer is burned).

The present embodiment improves the destruction resistance of a MOSFET (silicon carbide semiconductor device), particularly the resistance to a surge current_{IFSM} flowing between the source and drain when an inrush current flows in the MOSFET.

Hereinafter, embodiments of a silicon carbide semiconductor device according to the present disclosure will be described in detail with reference to the accompanying drawings. In the present specification and the accompanying drawings, layers and regions prefixed with n or p mean that majority carriers are electrons or holes, respectively. Further, + and − appended to n and p mean that the dopant concentration is higher or lower, respectively, than layers and regions without + and −. In the following description of the embodiments and the accompanying drawings, the same components are denoted by the same reference numerals, and redundant description thereof will be omitted.

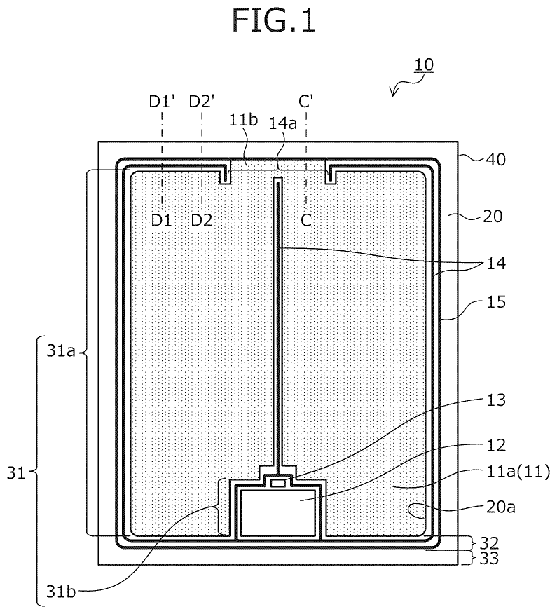

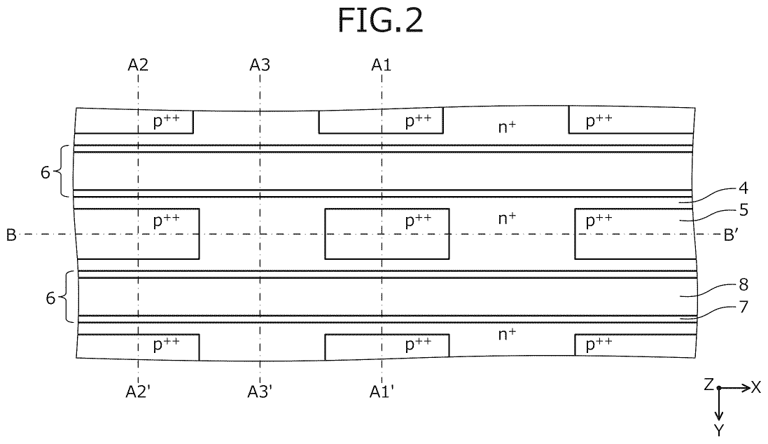

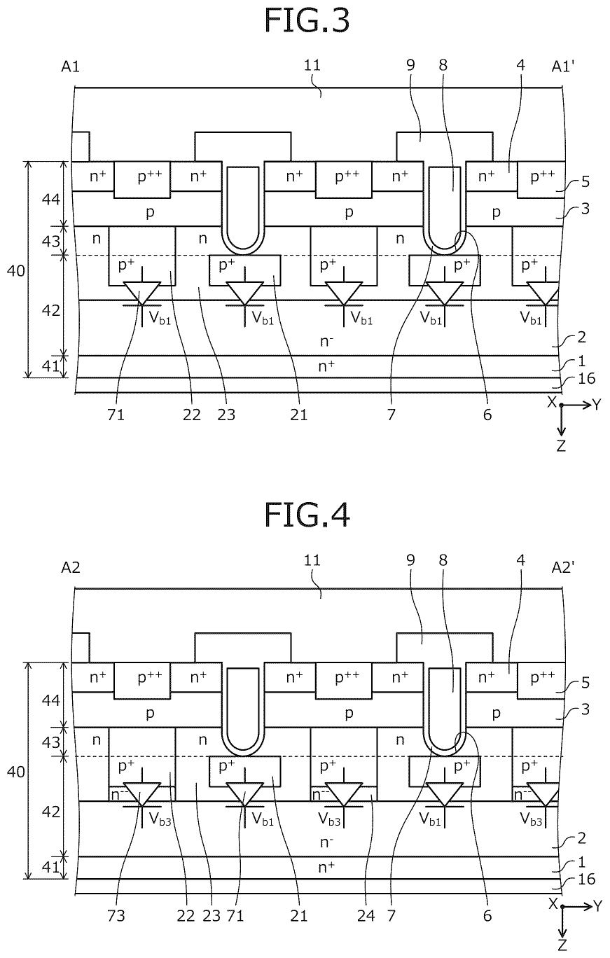

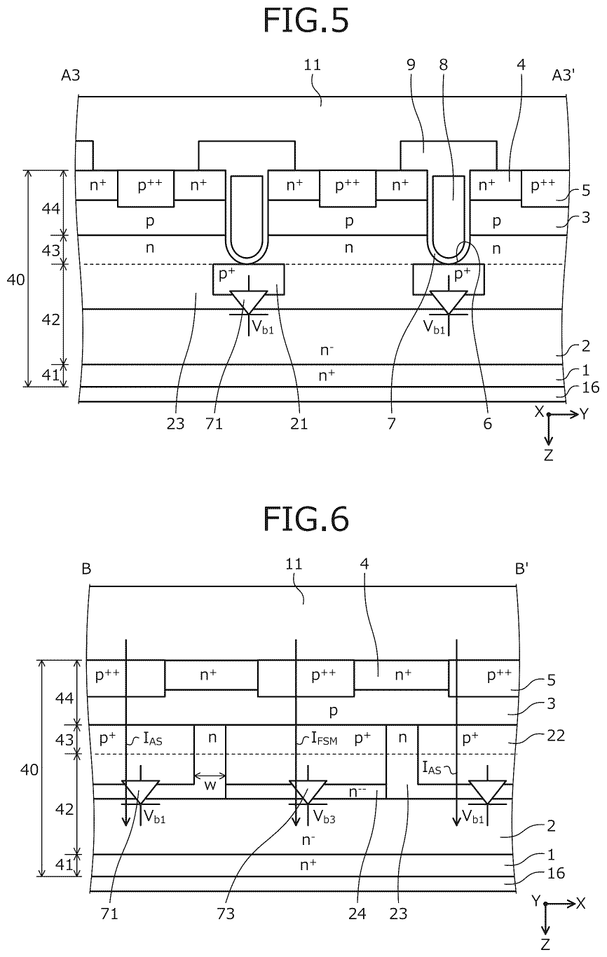

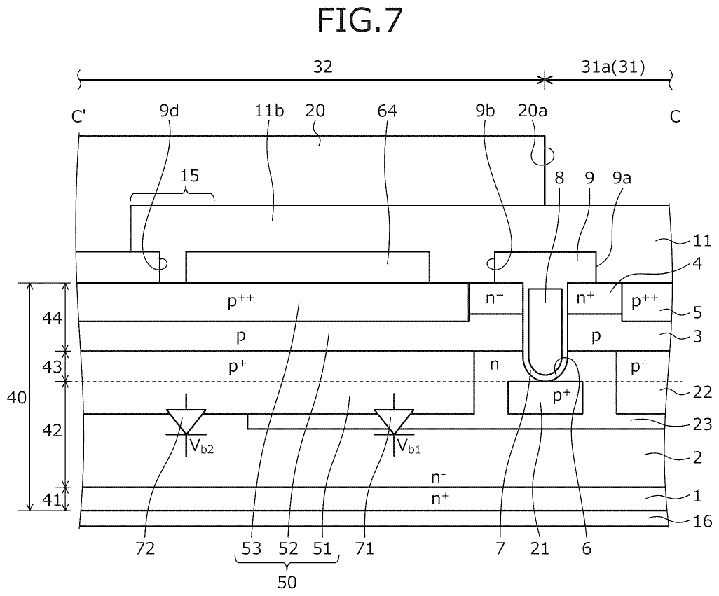

A silicon carbide semiconductor device according to an embodiment solving the above-described problem will be described below. FIG. 1 is a plan view depicting a layout of a silicon carbide semiconductor device according to an embodiment, as viewed from a front side of a semiconductor substrate thereof. FIG. 2 is a plan view depicting a layout of a cell structure of the active region of FIG. 1 as viewed from the front side of the semiconductor substrate. FIGS. 3, 4, 5, and 6 are cross-sectional views, respectively, depicting a structure along a cutting line A1-A1′, a cutting line A2-A2′, a cutting line A3-A3′, and a cutting line B-B′ depicted in FIG. 2. FIGS. 7, 8, and 9 are cross-sectional views, respectively, depicting the structure along a cutting line C-C′, a cutting line D1-D1′, and a cutting line D2-D2′ depicted in FIG. 1.

A silicon carbide semiconductor device 10 according to the embodiment depicted in FIGS. 1 to 9 is a vertical MOSFET having a trench gate structure (insulated gate structure having a metal-oxide film-semiconductor three-layer structure: device element structure) in which a gate finger 14 and a source ring 15 are provided in a boundary region 32 between an active region 31 and an edge termination region 33 of a semiconductor substrate (semiconductor chip) 40 containing silicon carbide (SiC) as a semiconductor material, the gate finger 14 and the source ring 15 being provided so as to surround the periphery of the active region 31. The active region 31 is a region through which a main current (drift current) flows when the MOSFET (silicon carbide semiconductor device 10) is on, and occupies most of the area (surface area) of the semiconductor substrate 40.

As depicted in FIG. 1, the active region 31 has, for example, a substantially rectangular planar shape, and is disposed substantially in a center (chip center) of the semiconductor substrate 40. In an effective region (effective active region) 31a of the active region 31, multiple cells each having the same MOSFET structure are arranged adjacent to each other and function as the MOSFET. A non-operating region (non-operating active region) 31b of the active region 31 is a region of the active region 31 excluding the effective active region 31a; the non-operating region 31b is free of MOSFET cells is arranged and does not function as a MOSFET. The boundary region 32 is adjacent to an outer side (side facing the chip end) of the active region 31 and surrounds the periphery of the active region 31 in a substantially rectangular shape, in a plan view.

The edge termination region 33 is a region between the boundary region 32 and the end portion (chip end portion) of the semiconductor substrate 40, is adjacent to an outer side of the boundary region 32, and surrounds the periphery of the boundary region 32 in a substantially rectangular shape, in a plan view. The edge termination region 33 has a function of relaxing electric field of the front side of the semiconductor substrate 40 to maintain a breakdown voltage. The breakdown voltage is a limit voltage at which an element does not malfunction or break down. In the edge termination region 33, for example, a predetermined voltage withstanding structure (not depicted) such as a guard ring structure, a field limiting ring (FLR) structure, or a junction termination extension (JTE) structure is disposed.

A source pad 11a (source electrode (first electrode) 11), a gate pad 12, a measurement pad 13, a gate finger 14, and a source ring (first wiring layer) 15 are disposed on the front surface of the semiconductor substrate 40. The source electrode 11, the gate pad 12, the measurement pad 13, a gate metal wiring layer 63 (described later) of the gate finger 14, and the source ring 15 are metal layers formed at a same level. The source electrode 11 is provided in the effective active region 31a and covers substantially the entire surface of the effective active region 31a. A portion of the source electrode 11 exposed in an opening 20a of a passivation film 20 functions as a source pad 11a (hatched portion).

A portion (convex portion) 11b of the source electrode 11 is connected to the source ring 15 at a partially opened portion 14a of the gate finger 14. The source electrode 11 may be divided into two or more. For example, the effective active regions 31a are arranged line-symmetrically with respect to the non-operating active region 31b (gate finger 14) linearly extending through the chip center, and the source electrodes 11 are arranged in the two effective active regions 31a, respectively. The convex portions 11b of the source electrodes 11 are connected to each other at the partially opened portion 14a of the gate finger 14. In each effective active region 31a, for example, multiple cells are arranged line-symmetrically with respect to the gate finger 14.

The gate pad 12, the measurement pad 13, and the gate resistor (not depicted) are disposed in the non-operating active region 31b. The measurement pad 13 is an electrode pad for measuring a gate resistance value and is connected to the gate finger 14. The gate resistor and the measurement pad 13 are arranged at a position relatively close to the gate pad 12. The gate finger 14 and source ring 15 are disposed apart from each other in boundary region 32 and have ring-shapes concentrically surrounding the periphery of active region 31, in a plan view. The gate finger 14 is disposed in boundary region 32. The gate finger 14 surrounds the periphery of the active region 31 in a substantially rectangular shape that is partially opened.

The gate finger 14 is electrically connected to gate pad 12 via a gate resistor. Gate electrodes 8 (see FIGS. 3 and 4) of all the cells of the MOSFET are electrically connected to the gate finger 14. The gate finger 14 may be further disposed in the non-operating active region 31b. FIG. 1 depicts a case where the gate finger 14 extends linearly in a direction parallel to the front surface of the semiconductor substrate 40 through the center of the chip. Conductive layers containing polysilicon (poly-Si), such as the gate resistor, the gate electrodes 8, and a gate polysilicon wiring layer 62 described later, are formed by, for example, ion implantation of an n-type dopant into polysilicon.

The source ring 15 is disposed closer to the chip end than is the gate finger 14 in the boundary region 32, and surrounds the periphery of the active region 31 in a substantially rectangular shape in a plan view. The source ring 15 is connected to a p-type outer peripheral region (fourth semiconductor region) 50 described later and is coupled to the convex portion 11b of the source electrode 11 at the partially opened portion 14a of the gate finger 14, the source ring 15 is fixed to the potential of the source electrode 11. The source ring 15 has a function of suppressing concentration of a hole current at an insulating layer 64 directly below the gate finger 14 (side facing the semiconductor substrate 40) when holes in an n⁻-type drift region 2 closer to the chip end than is the active region 31 are pulled out to the source electrode 11 when the MOSFET is off.

As depicted in FIGS. 2 to 6, the semiconductor substrate 40 is formed by stacking epitaxial layers 42 to 44, which constitute the n⁻-type drift region (second first-conductivity-type region) 2, an n-type current spreading region 23, and the p-type base region 3, in this order on the front surface of an n⁺-type starting substrate 41 containing SiC as a semiconductor material. The semiconductor substrate 40 has, as a front surface, a first main surface having the p-type epitaxial layer 44 side and, as a back surface, a second main surface having the n⁺-type starting substrate 41. The n⁺-type starting substrate 41 constitutes an n⁺-type drain region 1. In the effective active region 31a, a trench gate structure of the MOSFET is provided between the front surface of the semiconductor substrate 40 and the n⁻-type drift region 2.

The trench gate structure includes a p-type base region (second semiconductor region) 3, n⁺-type source regions (third semiconductor regions) 4, p⁺⁺-type contact regions 5, trenches 6, gate insulating films 7, and gate electrodes 8. The p-type base region 3 is provided between the front surface of the semiconductor substrate 40 and the n⁻-type drift region 2 over the entire region of the active region 31 and the boundary region 32. The n⁺-type source regions 4 and the p⁺⁺-type contact regions 5 are diffused regions formed in a surface region of the p-type epitaxial layer 44 by ion implantation. The n⁺-type source regions 4 and the p⁺⁺-type contact regions 5 are each selectively provided between the front surface of the semiconductor substrate 40 and the p-type base region 3 and are in contact with the p-type base region 3.

A portion of the p-type epitaxial layer 44 excluding the n⁺-type source regions 4, the p⁺⁺-type contact regions 5, and a p⁺⁺-type outer peripheral contact region 53 described later constitutes the p-type base region 3. The p-type base region 3, the n⁺-type source regions 4, and the n-type current spreading region 23 to be described later extend linearly in the longitudinal direction (first direction X) of the trenches 6 between the trenches 6 adjacent to each other, and respective ends thereof in the first direction X are in contact with the later-described p-type outer peripheral region 50. The p-type base region 3, the n⁺-type source regions 4, and the n-type current spreading region 23 described later are adjacent to sidewalls of the trenches 6 and face the gate electrodes 8 via the gate insulating films 7 at the sidewalls of the trenches 6.

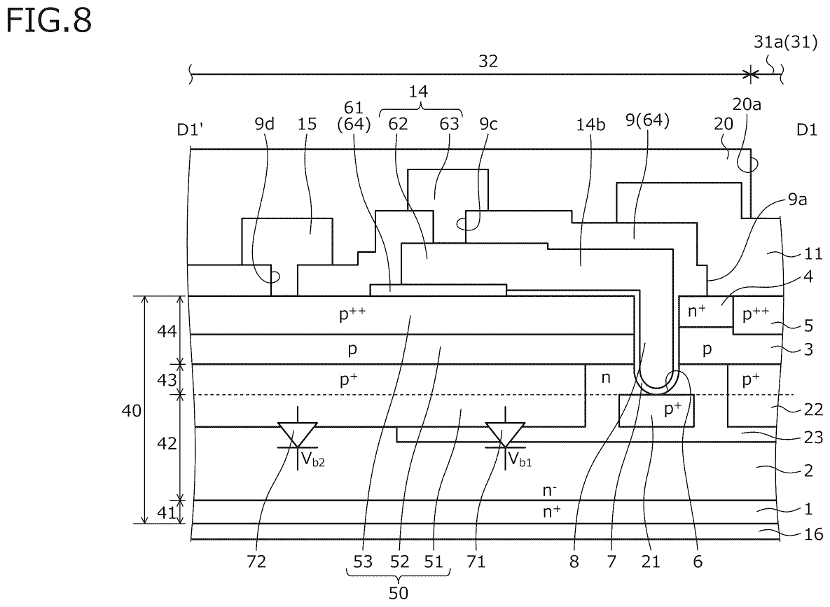

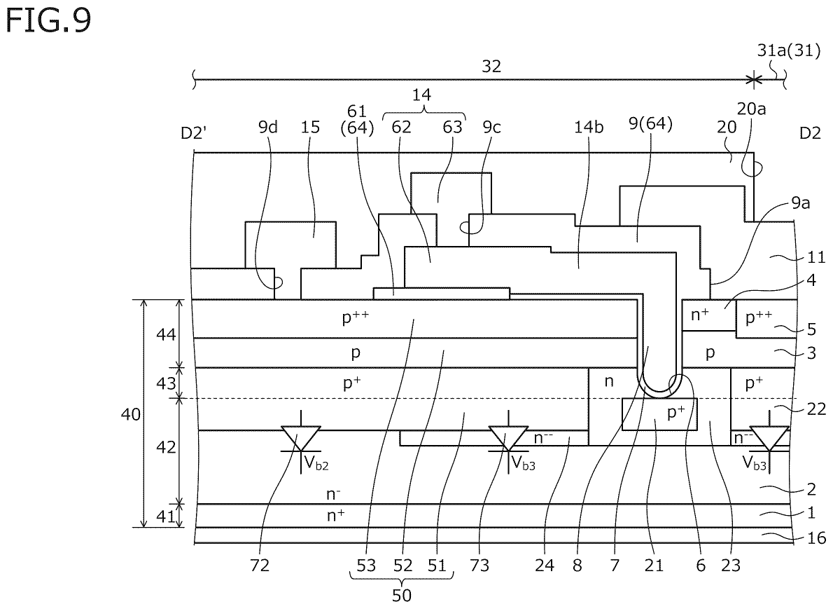

The p⁺⁺-type contact regions 5 are disposed between the trenches 6 adjacent to each other and are apart from the trenches 6. The p⁺⁺-type contact regions 5 may be arranged in a scattered manner in the longitudinal direction of the trenches 6. When viewed from the front side of the semiconductor substrate 40 (in a plan view), the periphery of each p⁺⁺-type contact regions 5 is bordered by the n⁺-type source regions 4. The p⁺⁺-type contact regions 5 may omitted. In this case, instead of the p⁺⁺-type contact regions 5, the p-type base region 3 reaches the front surface of the semiconductor substrate 40 (not depicted). Directly below a coupling portion 14b of the gate electrodes 8 and the gate finger 14 (side facing the n⁺-type drain region 1) is free of the n⁺-type source regions 4 (see FIGS. 8 and 9 described later).

The trenches 6 penetrate through the n⁺-type source regions 4 and the p-type base region 3 in the depth direction Z from the front surface of the semiconductor substrate 40 and terminate in the n-type current spreading region 23 described later. For example, the trenches 6 linearly extend in a first direction X (longitudinal direction) parallel to the front surface of the semiconductor substrate 40, are disposed adjacent to each other in a second direction Y (lateral direction) parallel to the front surface of the semiconductor substrate 40 and orthogonal to the first direction X, and form a striped pattern when viewed from the front side of the semiconductor substrate 40 (see FIG. 2). The gate electrodes 8 are provided in the trenches 6 via the gate insulating films 7.

Between the p-type base region 3 and the n⁻-type drift region 2, first p⁺-type regions (second-conductivity-type regions) 21, second p⁺-type regions 22 (second-conductivity-type regions), the n-type current spreading region (first first-conductivity-type region) 23, and n⁻⁻-type regions (first first-conductivity-type region or third first-conductivity-type regions) 24 are selectively provided at positions deeper toward the n⁺-type drain region 1 than are the bottoms of the trenches 6. The first p⁺-type regions 21 and the n⁻⁻-type regions 24 are diffused regions formed by ion implantation in surface regions of an n⁻-type epitaxial layer (first semiconductor region) 42. The second p⁺-type regions 22 and the n-type current spreading region 23 are diffused regions formed by ion implantation so as to be disposed from the n-type epitaxial layer (first semiconductor region) 43 to the surface region of the n⁻-type epitaxial layer 42 in the depth direction Z. When the n-type epitaxial layer 43 has the same dopant concentration as that of the n-type current spreading region 23, ion implantation for forming the n-type current spreading region 23 in the n-type epitaxial layer 43 may be omitted.

The first p⁺-type regions 21 and the second p⁺-type regions 22 are fixed to the potential of the source electrode 11, and have a function of relaxing the electric field in the vicinity of the bottoms of the trenches 6 by being depleted when the MOSFET is off (or by depleting the n-type current spreading region 23, or by both). The first p⁺-type regions (second second-conductivity-type regions) 21 are provided apart from the p-type base region 3 and face the bottoms of the trenches 6 in the depth direction Z. The first p⁺-type regions 21 may be in contact with the gate insulating films 7 at the bottoms of the trenches 6 or may be apart from the trenches 6. The first p⁺-type regions 21 linearly extend in the longitudinal direction (first direction X) of the trenches 6, have a length substantially the same as the length of each of the trenches 6 in the longitudinal direction, and have ends that are in contact with a later-described p⁺-type outer peripheral region 51, in the first direction X.

The second p⁺-type regions (first second-conductivity-type regions) 22 are provided between the trenches 6 adjacent to each other, the second p⁺-type regions 22 being apart from the trenches 6 and the first p⁺-type regions 21, and having an upper surface (surface facing the n⁺-type source regions 4) in contact with the p-type base region 3. The second p⁺-type regions 22 face the p⁺⁺-type contact regions 5 in the depth direction Z via the p-type base region 3. Each of the second p⁺-type regions 22 is formed by coupling, in the depth direction Z, a lower portion (portion facing the n⁺-type drain region 1) formed in a surface region of the n⁻-type epitaxial layer 42 and an upper portion (portion facing the n⁺-type source regions 4) formed in the n-type epitaxial layer 43. The lower portion of each of the second p⁺-type regions 22 may be formed simultaneously with the first p⁺-type regions 21.

The second p⁺-type regions 22 may be provided so as to be scattered in the longitudinal direction (first direction X) of the trenches 6. In a plan view, a periphery of each of the second p⁺-type regions 22 is bordered by the n-type current spreading region 23. It is sufficient that the second p⁺-type regions 22 face the p⁺⁺-type contact regions 5 in the depth direction Z with the p-type base region 3 interposed therebetween, and the intervals at which the second p⁺-type regions 22 are scattered in the first direction X may be different from the intervals at which the p⁺⁺-type contact regions 5 are scattered in the first direction X. Some of second p⁺-type regions 22 scattered in the first direction X may be coupled to the first p⁺-type regions 21. An interval w between the second p⁺-type regions 22 adjacent to each other in the first direction X may be, for example, about 1 μm or less.

When the interval w between the second p⁺-type regions 22 adjacent to each other in the first direction X exceeds the upper limit value and the avalanche current las flows through first body diodes 71, parasitic npn bipolar transistors in which the n⁺-type source regions 4 serve as an emitter, the p-type base region 3 serves as a base, and the n-type current spreading region 23 serves as a collector turns on, and a current easily flows. It has been experimentally confirmed by the inventors that the breakdown voltage of the MOSFET may be maintained by setting the interval w between the second p⁺-type regions 22 adjacent to each other in the first direction X within the above range.

The n-type current spreading region 23 is a so-called current spreading layer (CSL) that reduces spreading resistance of carriers (holes and electrons). The n-type current spreading region 23 is provided adjacent to the first p⁺-type regions 21, the second p⁺-type regions 22, and the n⁻⁻-type regions 24 between the first p⁺-type regions 21 and the second p⁺-type regions 22 adjacent to each other, and has an upper surface that is in contact with the p-type base region 3. The n-type current spreading region 23 extends in the second direction Y between the p-type base region 3 and the first p⁺-type regions 21 and reaches the trenches 6. The n-type current spreading region 23 reaches a position deeper on the n⁺-type drain region 1 side than are the first p⁺-type regions 21 and the second p⁺-type regions 22, and is in contact with the n⁻-type drift region 2 at the lower surface (surface facing the n⁺-type drain region 1) thereof.

The n-type current spreading region 23 borders the entire lower surface of each of the first p⁺-type regions 21. The n-type current spreading region 23 borders the lower surface of selective ones of the second p⁺-type regions 22. When the second p⁺-type regions 22 are scattered in the first direction X, the n-type current spreading region 23 borders the entire lower surface of some of the second p⁺-type regions 22. Of the second p⁺-type regions 22, the second p⁺-type regions 22 whose lower surface is not bordered by the n-type current spreading region 23, the entire lower surface thereof is bordered by the n⁻⁻-type regions 24. The n-type current spreading region 23 is provided over an entire area of the active region 31 excluding the portion where the n⁻⁻-type regions 24 is disposed. The entire lower surface of each of the second p⁺-type regions 22 is bordered by the n-type current spreading region 23 or the n⁻⁻-type regions 24.

The n-type current spreading region 23 extends from the active region 31 to the boundary region 32, and terminates closer to the active region 31 than is the source ring 15 (closer to the chip center) in the boundary region 32. The n-type current spreading region 23 borders the entire lower surface of the p⁺-type outer peripheral region 51 in the non-operating active region 31b, and borders the lower surface of a portion of the p⁺-type outer peripheral region 51 directly below the gate finger 14 in the boundary region 32. Therefore, the n-type current spreading region 23 faces the source electrode 11, the gate pad 12, the measurement pad 13, the gate finger 14, and the gate resistor in the depth direction Z, and does not face the source ring 15 in the depth direction Z. The n-type current spreading region 23 is formed by connecting a lower portion formed in a surface region of the n⁻-type epitaxial layer 42 and an upper portion formed in the n-type epitaxial layer 43 in the depth direction Z.

Since the resistance of the main current path of the MOSFET is reduced by the n-type current spreading region 23, the on-resistance of the MOSFET may be reduced. In addition, since the n-type current spreading region 23 reaches a position deeper toward the n⁺-type drain region 1 than is the p⁺-type outer peripheral region 51, avalanche breakdown may easily occur in the active region 31, which occupies most of the area of the semiconductor substrate 40. In addition, the resistance of the path of the forward current IF of the first body diodes 71 is reduced by the n-type current spreading region 23, and a current (hereinafter, referred to as an avalanche current) las generated by a rapid increase of carriers due to avalanche breakdown in the active region 31 easily flows to the first body diodes 71. Thus, the avalanche resistance may be improved.

Each of the first body diodes 71 is a parasitic pn diode formed by pn junctions between the p⁺⁺-type contact regions 5, the p-type base region 3, the first p⁺-type regions 21, and the second p⁺-type regions 22, the n-type current spreading region 23, and the n⁻-type drift region 2, and serves as a path of the avalanche current las. The avalanche current las easily flows from the source electrode 11 to the p⁺⁺-type contact regions 5. Therefore, by interspersing the p⁺⁺-type contact regions 5 and the second p⁺-type regions 22 in the first direction X so that the second p⁺-type regions 22 are disposed directly below the p⁺⁺-type contact regions 5 as described above, it is possible to effectively separate a region in which the avalanche current las easily flows (a region in which the first body diodes 71 is formed) and a region in which the surge current_{IFSM} described later easily flows (a region in which third body diodes 73 are formed).

Each of the n⁻⁻-type regions 24 is provided in an island-like shape between and in contact with the second p⁺-type regions 22 and the n⁻-type drift region 2. In a plan view, the periphery of each n⁻⁻-type regions 24 is bordered by the n-type current spreading region 23. When the second p⁺-type regions 22 are scattered in the first direction X, each of the n⁻⁻-type regions 24 is adjacent to a different one of second p⁺-type regions 22 in the depth direction Z. The third body diodes 73 are formed adjacent to the first body diodes 71 in the effective active region 31a by the n⁻⁻-type regions 24. Each of the third body diodes 73 is a parasitic pn diode formed by a pn junction between the p⁺⁺-type contact regions 5, the p-type base region 3, and the second p⁺-type regions 22, and the n⁻⁻-type regions 24 and the n⁻-type drift region 2. The third body diodes 73 serves as a path for a surge current_{IFSM} generated by a steep dV/dt (temporal change in voltage) of a drain-source voltage when an inrush current flows through the MOSFET.

A built-in voltage V_{b3} of the third body diodes 73 is lower than a built-in voltage V_{b1} of the first body diodes 71 (V_{b3}<V_{b1}). A reason for this is, as described above, the built-in voltage V_{bi} of a pn junction becomes higher as the acceptor density N_{A} and the donor density N_{d} become higher (see the above formula (1)). The first body diodes 71 and the third body diodes 73 have the same acceptor density N_{A} (p⁺⁺-type contact regions 5, p-type base region 3, and second p⁺-type regions 22) that determines the built-in voltages V_{b1} and V_{b3}. The donor density N_{d} (the dopant concentration of the n⁻⁻-type regions 24) that determines the built-in voltage V_{b3} of the third body diodes 73 is lower than the donor density N_{d} (the dopant concentration of the n-type current spreading region 23) that determines the built-in voltage V_{b1} of the first body diodes 71.

Further, the n⁻⁻-type regions 24 have a function of adjusting the n-type dopant concentration in the vicinity of the pn junction interface so that a portion where the built-in voltage V_{bi} of the main junction (pn junction) of the MOSFET is equal to or higher than that of the boundary region 32 is formed in the effective active region 31a. That is, the n⁻⁻-type regions 24 adjust the built-in voltage V_{b3} of the third body diodes 73 to be equal to or lower than the built-in voltage V_{b2} of a later-described second body diode 72 in the boundary region 32 (V_{b3}≤V_{b2}). The main junction of the MOSFET is a pn junction between a p-type region (the first p⁺-type regions 21, the second p⁺-type regions 22, and the p⁺-type outer peripheral region 51) fixed to the potential of the source electrode 11 and any n-type region of the n-type current spreading region 23, the n⁻-type drift region 2, and the n⁻⁻-type regions 24.

The dopant concentration of the n⁻⁻-type regions 24 may be substantially the same as the dopant concentration of the n⁻-type drift region 2. In this case, when the lower portion of the n-type current spreading region 23 is formed in the n⁻-type epitaxial layer 42 by ion implantation of an n-type dopant, the n⁻⁻-type regions 24 may be formed by covering portions corresponding to formation regions of the n⁻⁻-type regions 24 with an ion implantation mask and not performing ion implantation to the portions. When the dopant concentration of the n⁻⁻-type regions 24 is substantially the same as the dopant concentration of the n⁻-type drift region 2, the built-in voltage V_{b3} of the third body diodes 73 is the same as the built-in voltage V_{b2} of the second body diode 72, but the n⁻⁻-type regions 24 may be formed without addition processes.

In a case where the built-in voltage V_{b3} of the third body diodes 73 is equal to the built-in voltage V_{b2} of the second body diode 72 (V_{b3}=V_{b2}<V_{b1}), when the second body diode 72 conducts in the forward direction in the boundary region 32, the third body diodes 73 also conducts in the forward direction in the effective active region 31a. Since the third body diodes 73 conducts in the forward direction, the carrier density of the n⁻-type drift region 2 in the boundary region 32 when an inrush current flows in the MOSFET may be reduced as compared with the reference example (see FIGS. 10 to 14). Thus, even when the surge current_{IFSM} is generated when the inrush current flows through the MOSFET, the amount of the hole current flowing to the source ring 15 when the inrush current flows through the MOSFET is reduced as compared with the reference example, and the concentration of current at the source ring 15 may be suppressed. Thus, the resistance to the surge current_{IFSM} is improved.

Preferably, the built-in voltage V_{b3} of the third body diodes 73 may be lower than the built-in voltage V_{b2} of the second body diode 72 (V_{b3}<V_{b2}<V_{b1}). Therefore, preferably, the dopant concentration of the n⁻⁻-type regions 24 may be less than the dopant concentration of the n⁻-type drift region 2. In this case, the n⁻⁻-type regions 24 may be formed by lowering the n-type dopant concentration of the portions of the n-type epitaxial layer 42 corresponding to the formation regions of the n⁻⁻-type regions 24 by ion implantation of the p-type dopant to such an extent that the region is not inverted to the p-type. The ion implantation of the n-type dopant for forming the lower portion of the n-type current spreading region 23 may be performed in a state where portions corresponding to the formation regions of the n⁻⁻-type regions 24 are covered with an ion implantation mask.

In a case where the built-in voltage V_{b3} of the third body diodes 73 is lower than the built-in voltage V_{b2} of the second body diode 72, when an inrush current flows through the MOSFET, the third body diodes 73 conducts in the forward direction before the second body diode 72 conducts in the forward direction, and the forward current IF starts to flow preferentially through the third body diodes 73. As a result, the carrier density of the n-type drift region 2 in the boundary region 32 is further reduced when an inrush current flows through the MOSFET, and the amount of hole current flowing to the source ring 15 when the MOSFET is off is further reduced. Therefore, the resistance to the surge current_{IFSM} is further improved.

When the built-in voltage V_{b3} of the third body diodes 73 is set to be lower than the built-in voltage V_{b2} of the second body diode 72, even when the built-in voltage V_{b1} of the first body diodes 71 is substantially the same as the built-in voltage V_{b2} of the second body diode 72 (V_{b3}<V_{b2}=V_{b1}), the resistance to the surge current_{IFSM} may be improved. Therefore, when the built-in voltage V_{b3} of the third body diodes 73 is made lower than the built-in voltage V_{b2} of the second body diode 72 by providing the n⁻⁻-type regions 24, the built-in voltages V_{b1} and V_{b2} of the first body diodes 71 and the second body diode 72 may be made the same by, for example, omitting the n-type current spreading region 23 or extending the n-type current spreading region 23 between the p-type outer peripheral region 50 and the n⁻-type drift region 2 so as to face the source ring 15 in the depth direction.

When the n-type current spreading region 23 is omitted, instead of the n-type current spreading region 23, the n⁻-type drift region 2 extends between the first p⁺-type regions 21 and the second p⁺-type regions 22 adjacent to each other and reach the p-type base region 3, the n-type drift region 2 borders the entire lower surfaces of the first p⁺-type regions 21, selectively borders the lower surface of the second p⁺-type regions 22, and extends between the p-type base region 3 and the first p⁺-type regions 21 in the second direction Y to reach the trenches 6. Although not particularly limited, for example, the dimensions and dopant concentrations of the respective portions may have the following values. The dopant concentration of the n-type drift region 2 is, for example, about 3×10¹⁵/cm³. The dopant concentration of the n-type current spreading region 23 is, for example, about 1×10¹⁷/cm³. The thickness to the bottom surface of the n-type current spreading region 23 is about 0.5 μm. The dopant concentration of the n⁻⁻-type regions 24 is, for example, not less than about 1×10¹⁵/cm³ and not more than about 3×10¹⁵/cm³.

The n⁻⁻-type regions 24 are disposed at positions facing the p⁺⁺-type contact regions 5 via the second p⁺-type regions 22 and the p-type base region 3 in the depth direction Z. Since surge current_{IFSM} generated when an inrush current flows in the MOSFET easily flows from the source electrode 11 to the p⁺⁺-type contact regions 5, it is presumed that even when the n⁻⁻-type regions 24 are disposed at positions other than directly below the p⁺⁺-type contact regions 5, an effect of improving the resistance to the surge current_{IFSM} cannot be expected. When at least one of the n⁻⁻-type regions 24 is disposed, the effect of improving the resistance to the surge current_{IFSM} is obtained. The n⁻⁻-type regions 24 may border the entire lower surface of the second p⁺-type regions 22 adjacent thereto in the depth direction Z.

The n⁻⁻-type regions 24 may be interspersed in the first direction X between the trenches 6 adjacent to each another. In this case, the n⁻⁻-type regions 24 and the n-type current spreading region 23 may be disposed repeatedly alternating with each other and in the depth direction Z at predetermined intervals in the first direction X. The intervals at which the n⁻⁻-type regions 24 and the n-type current spreading region 23 are disposed repeatedly alternating with each other in the first direction X may be different from the intervals at which the p⁺⁺-type contact regions 5 are scattered in the first direction X. Preferably, the depth position of the lower surface of the n⁻⁻-type regions 24 may be substantially the same as the depth position of the lower surface of the n-type current spreading region 23. It is presumed that the effect obtained by the n⁻⁻-type regions 24 (improvement of the resistance to the surge current_{IFSM}) does not change even when the depth position of the lower surface of the n⁻⁻-type regions 24 is made deeper toward the n⁺-type drain region 1 side than the depth position of the lower surface of the n-type current spreading region 23.

A portion of the n⁻-type epitaxial layer 42 excluding the first p⁺-type regions 21, the second p⁺-type regions 22, the n-type current spreading region 23, the n⁻⁻-type regions 24, the p⁺-type outer peripheral region 51 described later, and a non-depicted voltage withstanding structure (for example, a p-type region such as a guard ring or an FLR, or an n⁺-type or p⁺-type channel stopper region) constitutes the n⁻-type drift region 2. The n⁻-type drift region 2 is provided from the active region 31 to the boundary region 32 and the edge termination region 33, and is exposed at the chip end (side surface of the semiconductor substrate 40). In the non-operating active region 31b, the p-type outer peripheral region 50 described later extends from the boundary region 32, in the entire region between the front surface of the semiconductor substrate 40 and the n⁻-type drift region 2.

In the non-operating active region 31b, the n-type current spreading region 23 extends from the effective active region 31a to form the first body diodes 71 in the entire region between the p-type outer peripheral region 50 (p⁺-type outer peripheral region 51) and the n⁻-type drift region 2. In the non-operating active region 31b, the n⁻⁻-type regions 24 may be selectively provided between and in contact with the p⁺-type outer peripheral region 51 and the n⁻-type drift region 2. That is, each of the n⁻⁻-type regions 24 may also be disposed in an island shape directly below the gate pad 12, the measurement pad 13, the gate finger 14, and the gate resistor. In a plan view, the periphery of the n⁻⁻-type regions 24 in the non-operating active region 31b is also bordered by the n-type current spreading region 23.

By disposing the n⁻⁻-type regions 24 also in the non-operating active region 31b, the area occupied by the n⁻⁻-type regions 24 is increased, and the resistance to the surge current_{IFSM} is further improved. Since the resistance to the surge current_{IFSM} at the coupling location between the source electrode 11 and the source ring 15 (the partially opened portion 14a of the gate finger 14) is improved, there is a possibility that the resistance to the surge current_{IFSM} at a portion away from the coupling location between the source electrode 11 and the source ring 15 (for example, directly below the gate pad 12 or directly below the measurement pad 13 in FIG. 1) is reduced. By disposing the n⁻⁻-type regions 24 at a location where there is a concern that the withstand capability with respect to the surge current_{IFSM} may decrease in this manner, decreases in the withstand capability with respect to the surge current_{IFSM} at the location may be suppressed.

The gate electrodes 8 are provided in the trenches 6 via the gate insulating films 7. An interlayer insulating film 9 is provided on the entire front surface of the semiconductor substrate 40 and covers the gate electrodes 8. The source electrode 11 is in ohmic contact with the n⁺-type source regions 4 and the p⁺⁺-type contact regions 5 in the contact holes 9a and 9b of the interlayer insulating film 9, and is electrically connected to the p-type base region 3, the n⁺-type source regions 4, and the p⁺⁺-type contact regions 5. A drain electrode (second electrode) 16 is provided in contact with the n⁺-type drain region 1 (n⁺-type starting substrate 41) on the entire back surface of the semiconductor substrate 40 (back surface of the n⁺-type starting substrate 41).

As depicted in FIGS. 7 to 9, the p-type outer peripheral region 50 is provided between the front surface of the semiconductor substrate 40 and the n⁻-type drift region 2 over substantially the entire region of the boundary region 32. The p-type outer peripheral region 50 surrounds the periphery of the active region 31 in the boundary region 32 and extends in the entire region between the front surface of the semiconductor substrate 40 and the n⁻-type drift region 2 in the non-operating active region 31b to surround the periphery of the effective active region 31a. The p-type outer peripheral region 50 is fixed to the potential of the source electrode 11 and has a function of extracting holes in the n⁻-type drift region 2 in the edge termination region 33 to the source electrode 11 or the source ring 15 when the MOSFET is off.

The p-type outer peripheral region 50 faces the entire surfaces of the gate pad 12, the measurement pad 13, the gate finger 14, the gate resistor, and the source ring 15 in the depth direction Z. In the boundary region 32, the n-type current spreading region 23 extends from the active region 31 to the entire region between the p-type outer peripheral region 50 directly below the gate finger 14 and the n⁻-type drift region 2 (FIG. 8). Therefore, the first body diodes 71 are formed immediately below the gate finger 14 in the boundary region 32, similarly to the non-operating active region 31b. The third body diodes 73 may be formed by providing the n⁻⁻-type regions 24 in island shapes at arbitrary locations directly below the gate finger 14 in the boundary region 32, similarly to the non-operating active region 31b (FIG. 9).

In the boundary region 32, the n-type current spreading region 23 terminates closer to the active region 31 than is the source ring 15 (on the chip center side) and does not face the source ring 15 in the depth direction Z. That is, the lower surface of the p-type outer peripheral region 50 in the boundary region 32 is in contact with the n-type current spreading region 23 only directly below the gate finger 14, and is in contact with the n⁻-type drift region 2 in a portion closer to the chip end than is the gate finger 14 (including directly below the source ring 15). Since the n-type current spreading region 23 is not disposed directly below the source ring 15, the built-in voltage V_{b2} of the second body diode 72 formed directly below the source ring 15 is lower than the built-in voltage V_{b1} of the first body diodes 71 in the effective active region 31a.

The second body diode 72 is a parasitic pn diode formed by a pn junction between the p-type outer peripheral region 50 and the n⁻-type drift region 2. Therefore, the built-in voltage V_{b2} of the second body diode 72 is equal to or higher than the built-in voltage V_{b3} of the third body diodes 73 described above. As described above, when an inrush current flows through the MOSFET, the second body diode 72 and the third body diodes 73 conduct in the forward direction at substantially the same timing, or the third body diodes 73 conduct in the forward direction earlier than the second body diode 72. Therefore, as compared with the reference example, concentration of current at the source ring 15 may be suppressed when the MOSFET is off, and the resistance to the surge current_{IFSM} may be improved.

In the p-type outer peripheral region 50, the p⁺-type outer peripheral region 51, a p-type outer peripheral base region 52, and the p⁺⁺-type outer peripheral contact region 53 are adjacent to each other in this order in the depth direction from the n⁺-type drain region 1. In a plan view, the layout of the p⁺-type outer peripheral region 51, the p-type outer peripheral base region 52, and the p⁺⁺-type outer peripheral contact region 53 is substantially the same (that is, substantially the same as that of the p-type outer peripheral region 50). The p⁺-type outer peripheral region 51 is a diffused region formed by ion implantation so as to be disposed from the n-type epitaxial layer 43 to the surface region of the n⁻-type epitaxial layer 42 in the depth direction Z. The p⁺-type outer peripheral region 51 is provided in contact with the n⁻-type drift region 2 and the n-type current spreading region 23 between the front surface of the semiconductor substrate 40 and the n⁻-type drift region 2.

Preferably, the dopant concentration and the depth position of the lower surface of the p⁺-type outer peripheral region 51 may be, respectively, the same as the dopant concentration and the depth position of the lower surface of the first p⁺-type regions 21. The p⁺-type outer peripheral region 51 may be formed simultaneously with the first p⁺-type regions 21, for example. The p⁺-type outer peripheral region 51 may extend toward the effective active region 31a and reach the sidewall of an outermost one the trenches 6. The p-type outer peripheral base region 52 is an extended portion (p-type epitaxial layer 44) of the p-type base region 3 extended to the boundary region 32. The p-type outer peripheral base region 52 is provided in contact with the p⁺-type outer peripheral region 51 in the entire region between the front surface of the semiconductor substrate 40 and the p⁺-type outer peripheral region 51. The p-type outer peripheral base region 52 reaches the sidewall of the outermost one of the trenches 6.

The p⁺⁺-type outer peripheral contact region 53 is a diffused region formed in a surface region of the p-type epitaxial layer 44 by ion implantation. The p⁺⁺-type outer peripheral contact region 53 is provided in contact with the p-type outer peripheral base region 52 in the entire region between the front surface of the semiconductor substrate 40 and the p-type outer peripheral base region 52. The p⁺⁺-type outer peripheral contact region 53 may extend toward the effective active region 31a and reach the sidewall of the outermost one of the trenches 6. The p⁺⁺-type outer peripheral contact region 53 may be formed simultaneously with the p⁺⁺-type contact regions 5. The p⁺⁺-type outer peripheral contact region 53 may be omitted. In this case, instead of the p⁺⁺-type outer peripheral contact region 53, the p-type outer peripheral base region 52 reaches the front surface of the semiconductor substrate 40.

The insulating layer 64 including the gate insulating films 7, the field oxide film 61, and the interlayer insulating film 9 is provided on the entire front surface of the semiconductor substrate 40 in the non-operating active region 31b, the boundary region 32, and the edge termination region 33. The insulating layer 64 covers the non-operating active region 31b, the p-type outer peripheral region 50 of the boundary region 32, and the voltage withstanding structure of the edge termination region 33. In the edge termination region 33, the front surface of the semiconductor substrate 40 is configured by the n⁻-type epitaxial layer 42 (n⁻-type drift region 2) (not depicted). The voltage withstanding structure of the edge termination region 33 is provided between the front surface of the semiconductor substrate 40 and the n⁻-type drift region 2.

The gate polysilicon wiring layer 62 and gate resistor (not depicted) are provided between the field oxide film 61 and the interlayer insulating film 9 in the non-operating active region 31b. The gate polysilicon wiring layer 62 is electrically connected to the gate pad 12 via the gate resistor. The gate electrodes 8 extend on the front surface of the semiconductor substrate 40 via the gate insulating films 7 and are coupled to the gate polysilicon wiring layer 62. The p-type outer peripheral region 50 is disposed over the entire region directly below the coupling portion (extended portion of the gate electrodes 8) 14b between the gate electrodes 8 and the gate finger 14 via the insulating layer 64.

The gate metal wiring layer 63 is provided on the gate polysilicon wiring layer 62 and is connected to the gate polysilicon wiring layer 62 via a contact hole 9c of the interlayer insulating film 9. The gate polysilicon wiring layer 62 and the gate metal wiring layer 63 constitute the gate finger 14. A gate polysilicon wiring layer (not depicted) is disposed directly below the gate pad 12 via the interlayer insulating film 9. The gate polysilicon wiring layer directly below the gate pad 12 is electrically connected to the gate polysilicon wiring layer 62 via the gate resistor. When the gate resistor is omitted, the gate pad 12 and the gate polysilicon wiring layer directly below the gate pad 12 may be in direct contact with each other.

In the insulating layer 64, contact holes 9b and 9d exposing the p⁺⁺-type outer peripheral contact region 53 are provided, respectively, on an inner side and an outer side of the gate finger 14. The source electrode 11 is in ohmic contact with the p⁺⁺-type outer peripheral contact region 53 in the contact hole 9b, is electrically connected to the p⁺⁺-type outer peripheral contact region 53, the p-type outer peripheral base region 52, and the p⁺-type outer peripheral region 51, and extends outward on the interlayer insulating film 9 to be coupled to the source ring 15. The source ring 15 is in ohmic contact with the p⁺⁺-type outer peripheral contact region 53 in the contact hole 9d and is electrically connected to the p⁺⁺-type outer peripheral contact region 53, the p-type outer peripheral base region 52, and the p⁺-type outer peripheral region 51.

The n-type current spreading region 23 extends from the active region 31 to the entire region between the p-type outer peripheral region 50 and the n⁻-type drift region 2 directly below the convex portion 11b of the source electrode 11, and the n⁻⁻-type regions 24 are not disposed (FIG. 7). Therefore, the first body diodes 71 is formed just below the convex portion 11b of the source electrode 11, similarly to the non-operating active region 31b. The passivation film 20 is a surface protective film that covers substantially the entire outermost surface of the front surface of the semiconductor substrate 40 (that is, the surface of the interlayer insulating film 9) and protects the front surface of the semiconductor substrate 40. The source pad 11a, the gate pad 12, and the measurement pad 13 are exposed in different openings of the passivation film 20.

Operation of the silicon carbide semiconductor device 10 (MOSFET) according to the embodiment will be described. When a voltage equal to or higher than the gate threshold voltage is applied to the gate electrodes 8 in a state where a positive voltage with respect to the source electrode 11 is applied to the drain electrode 16, a channel (n-type inversion layer) is formed along the sidewalls of the trenches 6 in a region of the p-type base region 3 between the n⁺-type source regions 4 and the n-type current spreading region 23. Thereby, a drift current (main current) flows from the n⁺⁺-type drain region 1 toward the n⁺-type source regions 4 through the n⁻-type drift region 2, the n-type current spreading region 23, and the channel, and the MOSFET turns on.

On the other hand, when the voltage applied to the gate electrodes 8 is less than the gate threshold voltage in a state in which a positive voltage with respect to the source electrode 11 is applied to the drain electrode 16, the p-n junction (main junction) between the p-type base region 3 and the first p⁺-type regions 21, the p-n junction (main junction) between the second p⁺-type regions 22 and the n-type current spreading region 23, and the p-n junction (main junction) between the second p⁺-type regions 22 and the n⁻-type drift region 2 are reverse-biased. A depletion layer spreads from the pn junction toward the source electrode 11 and the drain electrode 16 in the effective active region 31a, and the depletion layer spreads laterally from the effective active region 31a toward the non-operating active region 31b, the boundary region 32, and the edge termination region 33, thereby ensuring a predetermined breakdown voltage.

During a period in which the MOSFET transitions from on to off, a parasitic pn junction diode (body diode) formed by a pn junction between the p-type base region 3, the first p⁺-type regions 21, the second p⁺-type regions 22, and the p-type outer peripheral region 50, and the n-type current spreading region 23, the n⁻⁻-type regions 24, and the n-type drift region 2 conducts in a forward direction, and carriers are injected and accumulated in the n⁻-type drift region 2. At this time, the third body diodes 73 in the active region 31 conduct in the forward direction before or substantially at the same time that the second body diode 72 in the boundary region 32 conducts in the forward direction.

Thus, even when the surge current_{IFSM} is generated when the inrush current flows in the MOSFET, the carrier density of the n⁻-type drift region 2 in the boundary region 32 and the edge termination region 33 may be reduced. When the MOSFET transitions from this state to the off-state (reverse recovery of the body diode), the holes in the n⁻-type drift region 2 are discharged to the source electrode 11 or the source ring 15, and the MOSFET enters the off-state. Since the carrier density of the n⁻-type drift region 2 in the boundary region 32 and the edge termination region 33 is reduced as described above, the amount of the hole current flowing to the source ring 15 when the inrush current flows in the MOSFET is reduced and thus, the concentration of current at the source ring 15 is suppressed.

As described above, according to the embodiment, the n⁻⁻-type regions are selectively disposed between the second p⁺-type regions and the n⁻-type drift region, and the n-type dopant concentration of the portion in contact with the lower surface of the second p⁺-type regions is partially different. As a result, the built-in voltage of the pn junction (main junction of the MOSFET) in the effective active region may be partially made equal to or lower than the built-in voltage of the pn junction directly below the source ring. Therefore, when an inrush current flows in the MOSFET, a forward current preferentially flows in a part (third body diode) of the body diode in the effective active region, or a forward current simultaneously flows in the body diode directly below the source ring and the third body diode in the effective active region, and the carrier density of the n-type drift region directly below the source ring is reduced. Thus, concentration of current at the source pad and the source ring may be suppressed when the MOSFET is off, and the resistance to surge current may be improved, whereby the destruction resistance of the MOSFET is improved.

In the foregoing, the present disclosure is not limited to the above-described embodiments, and various modifications may be made without departing from the spirit of the present disclosure. In addition, in the embodiments, while the first conductivity type is assumed to be an n-type and the second conductivity type is assumed to be a p-type, the present disclosure is similarly implemented when the first conductivity type is a p-type and the second conductivity type is an n-type.

According to the silicon carbide semiconductor device of the present disclosure, it is possible to improve the breakdown tolerance.

As described, the silicon carbide semiconductor device according to the present disclosure is useful for power semiconductor devices used in power converting equipment, power source devices used in various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device comprising:
a semiconductor substrate having an active region, the semiconductor substrate having a first main surface and a second main surface opposite to each other;
a first semiconductor region of a first conductivity type, provided in the semiconductor substrate;
a second semiconductor region of a second conductivity type, provided in the active region of the semiconductor substrate, between the first main surface and the first semiconductor region;
a plurality of third semiconductor regions of the first conductivity type, selectively provided in the semiconductor substrate between the first main surface and the second semiconductor region;
a plurality of trenches penetrating through the plurality of third semiconductor regions and the second semiconductor region in a depth direction of the silicon carbide semiconductor device;
a gate insulating film provided in each of the plurality of trenches;
a plurality of gate electrodes provided in the plurality of trenches via the gate insulating films, respectively;
a plurality of second-conductivity-type regions selectively provided in the semiconductor substrate between the second semiconductor region and the first semiconductor region, reaching a position closer to the second main surface of the semiconductor substrate than are bottoms of the plurality of trenches, the plurality of second-conductivity-type regions being in contact with the first semiconductor region;
a first electrode provided on the first main surface in the active region and electrically connected to the plurality of third semiconductor regions, the second semiconductor region and the plurality of second-conductivity-type regions;
a second electrode provided on the second main surface;
a fourth semiconductor region of the second conductivity type, provided in the semiconductor substrate between the first main surface and the first semiconductor region, and surrounding a periphery of the active region in a plan view of the silicon carbide semiconductor device, the fourth semiconductor region reaching a position closer to the second main surface than are the bottoms of the plurality of trenches and being in contact with the first semiconductor region; and
a first wiring layer provided on the first main surface to surround the periphery of the active region, the first wiring layer being connected to a portion of the first electrode and being electrically connected to the fourth semiconductor region, the first wiring layer facing the fourth semiconductor region in the depth direction, wherein
the plurality of second-conductivity-type regions includes a plurality of first second-conductivity-type regions provided apart from the plurality of trenches and in contact with the second semiconductor region, each of the plurality of first second-conductivity-type regions having a surface that faces the second main surface, and
the first semiconductor region includes a first first-conductivity-type region having a dopant concentration different from that of the rest of the first semiconductor region, the first first-conductivity-type region being in contact with said surfaces of the plurality of first second-conductivity-type regions.

2. The silicon carbide semiconductor device according to claim 1, wherein
the first semiconductor region further has a second first-conductivity-type region different from the first first-conductivity-type region, and
the dopant concentration of the first first-conductivity-type region is higher than a dopant concentration of the second first-conductivity-type region.

3. The silicon carbide semiconductor device according to claim 2, wherein the first first-conductivity-type region is provided between the second semiconductor region and the second first-conductivity-type region, reaches a position closer to the second main surface than is the plurality of first second-conductivity-type regions, and selectively borders said surfaces of the plurality of first second-conductivity-type regions.

4. The silicon carbide semiconductor device according to claim 2, wherein the first semiconductor region further selectively includes a plurality of third first-conductivity-type regions between the second first-conductivity-type region and the plurality of first second-conductivity-type regions, the plurality of third first-conductivity-type regions being adjacent to the first first-conductivity-type region and having a dopant concentration lower than that of the second first-conductivity-type region.

5. The silicon carbide semiconductor device according to claim 1, wherein
the first semiconductor region further has a second first-conductivity-type region different from the first first-conductivity-type region, and
the dopant concentration of the first first-conductivity-type region is lower than a dopant concentration of the second first-conductivity-type region.

6. The silicon carbide semiconductor device according to claim 5, wherein the first first-conductivity-type region is provided between the second first-conductivity-type region and the plurality of first second-conductivity-type regions.

7. The silicon carbide semiconductor device according to claim 2, wherein
the plurality of trenches extends linearly in a first direction parallel to the first main surface of the semiconductor substrate,
the plurality of first second-conductivity-type regions is provided at a predetermined interval in the first direction, and
the first first-conductivity-type region borders each of the plurality of first second-conductivity-type regions, reaches a position closer to the second main surface than is the plurality of first second-conductivity-type regions, and selectively borders said surfaces of the plurality of first second-conductivity-type regions.

8. The silicon carbide semiconductor device according to claim 5, wherein
the plurality of trenches extends linearly in a first direction parallel to the first main surface of the semiconductor substrate,
the plurality of first second-conductivity-type regions is provided at a predetermined interval in the first direction, and
the first first-conductivity-type region has a plurality of portions each in an island-like shape, and each adjacent to a different one of the plurality of first second-conductivity-type regions in the depth direction.

9. The silicon carbide semiconductor device according to claim 7, wherein the predetermined interval is 1 μm or less.

10. The silicon carbide semiconductor device according to claim 8, wherein the predetermined interval is 1 μm or less.

11. The silicon carbide semiconductor device according to claim 7, wherein the plurality of second-conductivity-type regions includes a plurality of second second-conductivity-type regions facing the bottoms of the plurality of trenches, respectively, and extending linearly in the first direction.

12. The silicon carbide semiconductor device according to claim 8, wherein the plurality of second-conductivity-type regions includes a plurality of second second-conductivity-type regions facing the bottoms of the plurality of trenches, respectively, and extending linearly in the first direction.
